(19) United States
(12) Patent Application Publication
(10) Pub. No.: US 2015/0076652 A1
(43) Pub. Date: Mar. 19, 2015

(54) POWER SEMICONDUCTOR DEVICE

(71) Applicant: SAMSUNG ELECTRO-MECHANICS CO., LTD., Suwon (KR)

(72) Inventors: Chang Su JANG, Suwon (KR); Kee Ju UM, Suwon (KR); In Hyuk SONG, Suwon (KR); Jaehoon PARK, Suwon (KR); Dong Soo SEO, Suwon (KR)

(73) Assignee: SAMSUNG ELECTRO-MECHANICS CO., LTD., Suwon (KR)

(21) Appl. No.: 14/101,066

(22) Filed: Dec. 9, 2013

(30) Foreign Application Priority Data
Sep. 16, 2013 (KR) 10-2013-0111142

(51) Int. Cl. H01L 29/06; H01L 29/861

(52) U.S. Cl. CPC H01L 29/0661; H01L 29/861
USPC 257/487

(57) ABSTRACT

There is provided a power semiconductor device, including: a first semiconductor layer of a first conductive type having a thickness of t1 so as to withstand a reverse voltage of 600V; and a second semiconductor layer of a second conductive type formed inside an upper portion of the first semiconductor layer and having a thickness of t2, wherein t1/t2 is 15 to 18.

### CROSS-REFERENCE TO RELATED APPLICATIONS

This application claims the benefit of Korean Patent Application No. 10-2013-0111142 filed on Sep. 16, 2013, with the Korean Intellectual Property Office, the disclosure of which is incorporated herein by reference.

### BACKGROUND

The present disclosure relates to a power semiconductor device.

A diode refers to a power semiconductor device having an effect such as a light emitting property, a rectifying property, or the like.

The diode is configured by a p-n junction formed by attaching a p-type semiconductor and an n-type semiconductor to each other.

If the p-n junction is formed by attaching the p-type semiconductor and the n-type semiconductor to each other, electrons present in the n-type semiconductor are diffused into the p-type semiconductor having many holes.

The electrons diffused as mentioned above are combined with the holes in the p-type semiconductor, such that a depletion region where no carriers are present is formed at a p-n junction portion.

When a positive voltage is applied to the p-type semiconductor and a negative voltage is applied to the n-type semiconductor, the depletion region is eliminated, such that a current flows through the diode.

Conversely, when a reverse-bias is applied in which a negative voltage is applied to the p-type semiconductor and a positive voltage is applied to the n-type semiconductor, the depletion region is further widened and the carriers are not present, such that the current does not flow through the diode.

That is, in a reverse-bias region, the current passing through the diode is extremely small.

However, when a reverse limit voltage or a voltage beyond a withstand voltage is supplied, the diode causes an avalanche breakdown and a large current flows backwards, thereby damaging a device.

By decreasing a concentration and making a thickness thick in an n-type semiconductor region of the diode, the reverse limit voltage may be improved.

However, when the thickness of the n-type semiconductor region is increased, a forward voltage drop increases.

Thus, a method of increasing the reverse limit voltage while decreasing the forward voltage drop is required.

Recently, a fast switching diode has been required to have fast switching characteristics and soft recovery characteristics.

Since the p-n junction diode, which is generally used among diodes, uses few carriers, it may decrease a forward voltage by a conduction modulation effect.

However, since the few carriers have reverse recovery characteristics, the fast switching characteristics are degraded.

The reverse recovery characteristics refer to a current flowing until the few carriers are drained or eliminated in the case in which a large reverse current momentarily flows due to movement in a backward direction of the few carriers injected into the p-n junction when the voltage is rapidly applied in the backward direction in a state in which the forward current flows in the p-n junction diode.

The fast switching diode has the soft recovery characteristics by shortening a period (reverse recover time; trr) until the reverse current becomes zero and smoothing a reverse current waveform.

The fast switching diode is mainly classified into a fast recovery diode (FRD), a high efficiency diode (HED), and a Schottky barrier diode (SBD).

Among these, the FRD is a diode having the same structure as the general p-n diode, but capable of rapidly eliminating the few carriers after being turned off by diffusing impurities such as platinum, gold, and the like, or impurities due to electron beam, neutron irradiation, and the like, into a silicon to thereby increase a recombination center of electrons and holes.

However, since the above-mentioned FRD increases the recombination center by electron beam, neutron irradiation, heavy metal diffusion, and the like, it adversely increases the forward voltage drop to thereby add power.

Therefore, the fast switching characteristics and the soft recovery characteristics increasing the recombination center while not weighting the forward voltage drop are required.

Patent Document 1 described in the following related art document relates to a fast switching diode having a small leakage current.

Specifically, the disclosure in Patent Document 1 relates to a fast recovery diode including a first n-type layer having a first conductivity and including an upper surface, a lower surface, a first edge, and a second edge provided to an opposite side of the first edge; a first p-type region provided in the vicinity of the upper surface of the first n-type layer, having a first depth and including platinum; a second n-type region provided in the vicinity of the first edge of the first n-type layer and extended from the upper surface of the first n-type layer at a second depth, wherein the second depth is deeper than the first depth in order to decrease a leakage current; a first electrode provided in the vicinity of the upper surface of the first n-type layer; and a second electrode provided in the vicinity of the lower surface of the first n-type layer.

However, the disclosure in Patent Document 1 does not disclose a ratio of a thickness of the first n-type layer to a thickness of the first p-type region (emitter region).

Therefore, an effect simultaneously having high reverse limit voltage characteristics and smooth recovery characteristics based on the ratio of the thickness of the first n-type layer to the thickness of the first p-type region may not take place.

### RELATED ART DOCUMENT

(Patent Document 1) Korean Patent Laid-Open Publication No. 2006-0044955

### SUMMARY

An aspect of the present disclosure may provide a power semiconductor device having a low forward voltage drop, smooth recovery characteristics, and a high reverse limit voltage.

According to an aspect of the present disclosure, a power semiconductor device may include: a first semiconductor layer of a first conductive type, having a thickness of t1 so as to withstand a reverse voltage of 600V; and a second semiconductor layer of a second conductive type, formed inside an upper portion of the first semiconductor layer and having a thickness of t2, wherein t1/t2 is 15 to 18.

The t1 may be 60 μm to 70 μm.

The t2 may be 3.34 μm to 4.67 μm.

The power semiconductor device may further include a third semiconductor layer of the second conductive type, formed inside an upper portion of the second semiconductor layer and having an impurity concentration higher than that of the second semiconductor layer.

When a thickness of the third semiconductor layer is defined as t3, t2/t3 may be 2.5 to 4.5.

The t3 may be 0.75 μm to 1.86 μm.

The power semiconductor device may further include a fourth semiconductor region of the first conductive type, formed on a lower portion of the first semiconductor layer and having an impurity concentration higher than that of the first semiconductor layer.

The power semiconductor device may further include: an anode metal layer formed on an upper portion of the second semiconductor layer; and a cathode metal layer formed on a lower portion of the first semiconductor layer.

According to another aspect of the present disclosure, a power semiconductor device may include: a first semiconductor layer of a first conductive type, having a thickness of t1 so as to withstand a reverse voltage of 1200V; and a second semiconductor layer of a second conductive type, formed inside an upper portion of the first semiconductor layer and having a thickness of t2, wherein t1/t2 is 25 to 33.

The t1 may be 100 μm to 130 μm.

The t2 may be 3.04 μm to 5.03 μm.

The power semiconductor device may further include a third semiconductor layer of the second conductive type, formed inside an upper portion of the second semiconductor layer and having an impurity concentration higher than that of the second semiconductor layer.

When a thickness of the third semiconductor layer is defined as t3, t2/t3 may be 3 to 5.

The t3 may be 0.61 μm to 1.67 μm.

The power semiconductor device may further include a fourth semiconductor region of the first conductive type formed on a lower portion of the first semiconductor layer and having an impurity concentration higher than that of the first semiconductor layer.

The power semiconductor device may further include: an anode metal layer formed on an upper portion of the second semiconductor layer; and a cathode metal layer formed on a lower portion of the first semiconductor layer.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a cross-sectional view schematically showing a power semiconductor device according to an exemplary embodiment of the present disclosure;

FIG. 2 is a graph showing a VF value and a trr value according to a t1/t2 value of the power semiconductor device capable of withstanding a reverse voltage of 600V;

FIG. 3 is a graph showing a VF value and a trr value according to a t1/t2 value of the power semiconductor device capable of withstanding a reverse voltage of 1,200V;

FIG. 4 is a cross-sectional view schematically showing a power semiconductor device according to another exemplary embodiment of the present disclosure;

FIG. 5 is a graph showing a VR value according to a t2/t3 value of the power semiconductor device capable of withstanding a reverse voltage of 600V; and

FIG. 6 is a graph showing a VR value according to a t2/t3 value of the power semiconductor device capable of withstanding a reverse voltage of 1,200V.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

In the drawings, an x direction refers to a width direction, a y direction refers to a length direction, and a z direction refers to a height direction.

A power switch may be implemented by any one of a power MOSFET, an IGBT, a thyristor, and those similar to those mentioned above. Most new technologies disclosed in the present disclosure will be described based on a diode. However, exemplary embodiments of the present disclosure disclosed in the specification are not limited to the diode, but may generally be applied to different forms of power switch technologies including the power MOSFET and several forms of thyristors, in addition to the diode. Further, several exemplary embodiments of the present disclosure are illustrated as including specific p-type and n-type regions. However, other exemplary embodiments of the present disclosure may also be equally applied to elements in which several regions disclosed in the specification have opposite conductive types.

In addition, the n-type or the p-type used in the specification may be defined as a first conductive type or a second conductive type. Meanwhile, the first conductive type and the second conductive type refer to conductive types different from each other.

In addition, “positive (+)” generally refers to a high concentration doped state and “negative (−)” refers to a low concentration doped state.

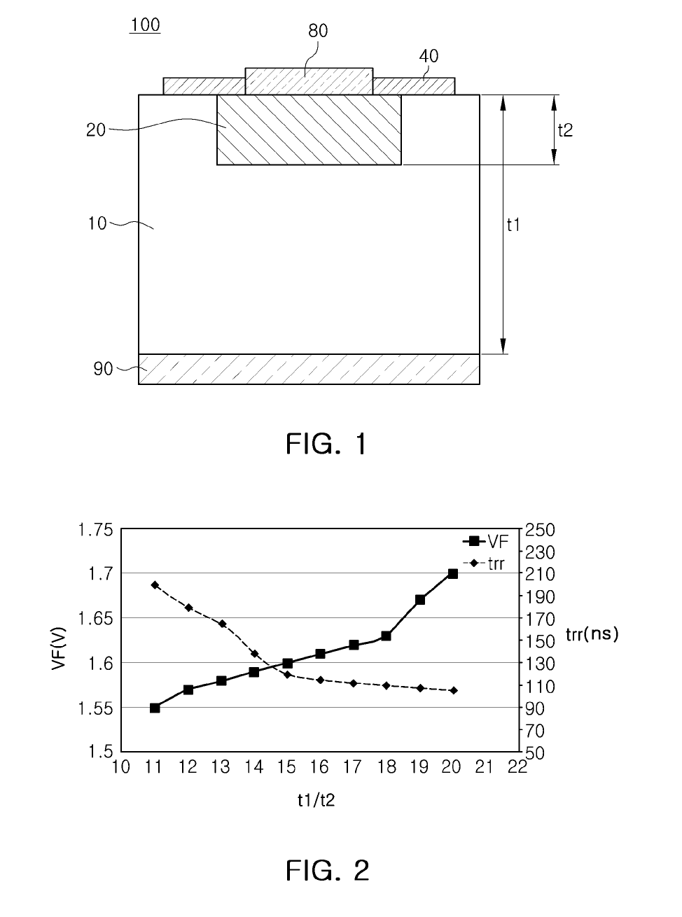

FIG. 1 is a cross-sectional view schematically showing a power semiconductor device according to an exemplary embodiment of the present disclosure.

Referring to FIG. 1, a power semiconductor device 100 according to an exemplary embodiment of the present disclosure may include a first semiconductor layer 10 of a first conductive type having a thickness of t1, and a second semiconductor layer 20 of a second conductive type formed inside an upper portion of the first semiconductor layer 10 and having a thickness of t2, wherein t1/t2 may be 15 to 18.

The first conductive type may be an n-type, and the second conductive type may be a p-type.

The first semiconductor layer 10 may generally be an n-type drift layer having a low concentration.

The first semiconductor layer 10 may be prepared using an epitaxial deposition so as to include an n-type impurity.

The first semiconductor layer 10 may be prepared to have a thickness of t1 or greater.

After the first semiconductor layer 10 is prepared to have the thickness of t1 or greater, the thickness of the first semiconductor layer 10 may be adjusted to be t1 by forming necessary configurations on an upper surface of the first semiconductor layer 10 and removing a portion of a lower surface of the first semiconductor layer 10.

The second semiconductor layer 20 may be formed by injecting an impurity of the second conductive type into the upper surface of the first semiconductor layer 10.

In order to form the second semiconductor layer 20 only at a desired portion, an insulation layer 40 may be formed on the upper surface of the first semiconductor layer 10.

The second semiconductor layer 20 may be formed only at the desired portion by forming the insulation layer 40 on the upper surface of the first semiconductor layer 10 and removing a portion thereof in which the second semiconductor layer 20 will be formed, and then injecting the impurity of the second conductive type therein.

The second semiconductor layer 20 may be formed to have the thickness of t2 by injecting the impurity of the second conductive type.

The second semiconductor layer 20 may further have an anode metal layer 80 formed on an upper surface thereof.

In addition, the first semiconductor layer 10 may further have a cathode metal layer 90 formed on a lower surface thereof.

FIG. 2 is a graph showing a VF value and a trr value according to a t1/t2 value of the power semiconductor device 100 capable of withstanding a reverse voltage of 600V.

In FIG. 2, VF refers to a forward voltage drop of the power semiconductor device 100, and trr refers to a time taken when a flow of current applied to the power semiconductor device 100 is changed from a forward direction to a backward direction.

Referring to FIG. 2, it may be seen that the power semiconductor device 100 according to the exemplary embodiment of the present disclosure has an increased VF value in accordance with an increase in the t1/t2 value.

The VF value is gradually increased in the case in which the t1/t2 value is 18 or less, but a gradient thereof is sharply increased from the point in which the t1/t2 value exceeds 18.

That is, in the case in which the t1/t2 value exceeds 18, since the forward voltage drop becomes too large, loss in the power semiconductor device is too large, such that it is difficult to be used in an electronic apparatus, and the like.

In general, the trr value is used as an index representing reverse recovery characteristics of the power semiconductor device.

The reverse recovery characteristics refer to a current flowing until a few carriers are drained or eliminated in the case in which a large reverse current instantaneously flows due to movements in a backward direction of the few carriers injected into a p-n junction when the voltage is rapidly applied in the backward direction in a state in which the forward current flows in a p-n junction diode.

A fast switching diode may refer to a diode having soft recovery characteristics by shortening a period (reverse recover time; trr) until a level of the reverse current becomes zero and smoothing a reverse current waveform.

Referring to the trr value of FIG. 2, the trr value of the power semiconductor device 100 capable of withstanding the reverse voltage of 600V is decreased to 120 ns or less in the case in which the t1/t2 value is 15 or greater.

The trr value of the power semiconductor device 100 capable of withstanding the reverse voltage of 600V may exceed 120 ns in the case in which the t1/t2 value is less than 15, but may be 120 ns or less in the case in which the t1/t2 value is 15 or greater, thereby having excellent reverse recovery characteristics.

As a result, the power semiconductor device 100 capable of withstanding the reverse voltage of 600V in the case in which the t1/t2 value is 15 to 18 may have a low forward voltage drop (VF) and the excellent reverse recovery characteristics.

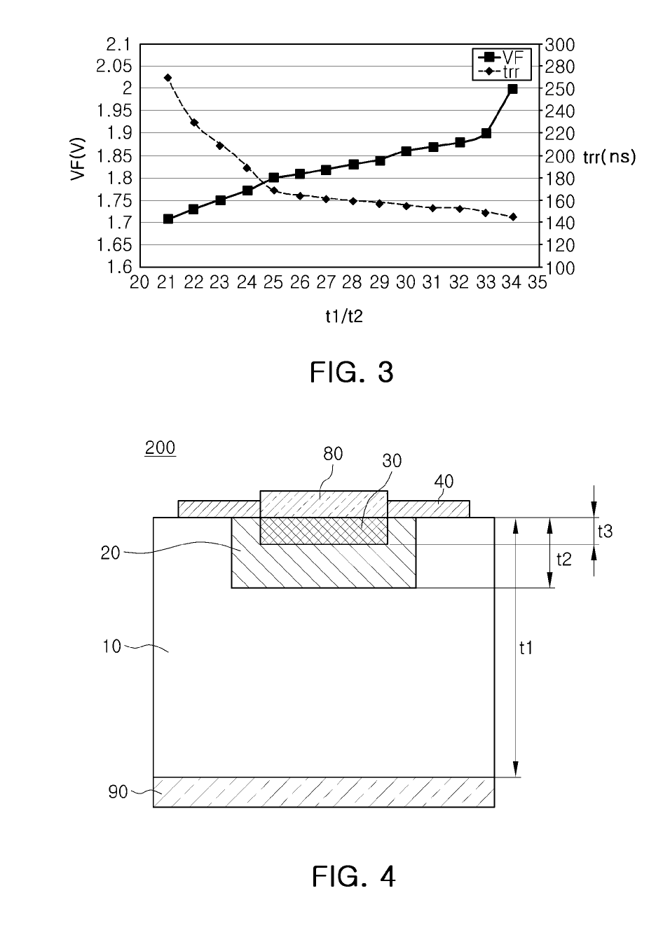

FIG. 3 is a graph showing a VF value and a trr value according to a t1/t2 value of the power semiconductor device 100 capable of withstanding a reverse voltage of 1200V.

In FIG. 3, VF refers to a forward voltage drop of the power semiconductor device 100, and trr refers to a time taken when the flow of current applied to the power semiconductor device 100 is changed from a forward direction to a backward direction.

Referring to FIG. 3, it may be seen that the power semiconductor device 100 according to the exemplary embodiment of the present disclosure has an increased VF value in accordance with an increase in the t1/t2 value.

The VF value is gradually increased in the case in which the t1/t2 value is 33 or less, but a gradient thereof is sharply increased from the point in which the t1/t2 value exceeds 33.

That is, in the case in which the t1/t2 value exceeds 33, since the forward voltage drop becomes too large, loss in the power semiconductor device is too large, such that it is difficult to be used in an electronic apparatus, and the like.

In general, the trr value is used as an index representing reverse recovery characteristics of the power semiconductor device.

The reverse recovery characteristics refer to a current flowing until a few carriers are drained or eliminated in the case in which a large reverse current instantaneously flows due to movements in the backward direction of the few carriers injected into a p-n junction when the voltage is rapidly applied in the backward direction in a state in which the forward current flows in a p-n junction diode.

The fast switching diode may refer to a diode having soft recovery characteristics by shortening a period (reverse recover time; trr) until a level of the reverse current becomes zero and smoothing a reverse current waveform.

Referring to the trr value of FIG. 3, the trr value of the power semiconductor device 100 capable of withstanding the reverse voltage of 1200V is decreased to 170 ns or less in the case in which the t1/t2 value is 25 or greater.

The trr value of the power semiconductor device 100 capable of withstanding the reverse voltage of 1200V may exceed 170 ns in the case in which the t1/t2 value is less than 25, but may be 170 ns or less in the case in which the t1/t2 value is 25 or greater, thereby having excellent reverse recovery characteristics.

As a result, the power semiconductor device 100 capable of withstanding the reverse voltage of 1200V in the case in which the t1/t2 value is 25 to 33 may have the low forward voltage drop (VF) as well as excellent reverse recovery characteristics.

FIG. 4 is a cross-sectional view schematically showing a power semiconductor device 200 according to another exemplary embodiment of the present disclosure.

The power semiconductor device 200 according to another exemplary embodiment of the present disclosure may further include a third semiconductor layer 30 of the second conductivity type formed inside an upper portion of the second semiconductor layer 20 and having an impurity concentration higher than that of the second semiconductor layer 20.

The third semiconductor layer 30 may serve as a field stop.

In the case in which a thickness t3 of the third semiconductor layer 30 is extremely small, a reach through phenomenon in which a depletion layer contacts the anode metal layer 80 to thereby cause an excessive flow of current may be generated, such that a withstand voltage becomes small.

Conversely, in the case in which the thickness t3 of the third semiconductor layer 30 is extremely large, an interval t2-t3 between the third semiconductor layer 30 and the second semiconductor layer 20 may be excessively narrow, such that the withstand voltage becomes small.

In addition, since the third semiconductor layer 30 has the impurity concentration higher than that of the second semiconductor layer 20, if the thickness of the third semiconductor layer 30 is greater, an anode concentration is controlled by the third semiconductor layer 30, such that the trr value may be increased and a Irr value may also be increased, thereby deteriorating reverse voltage characteristics.

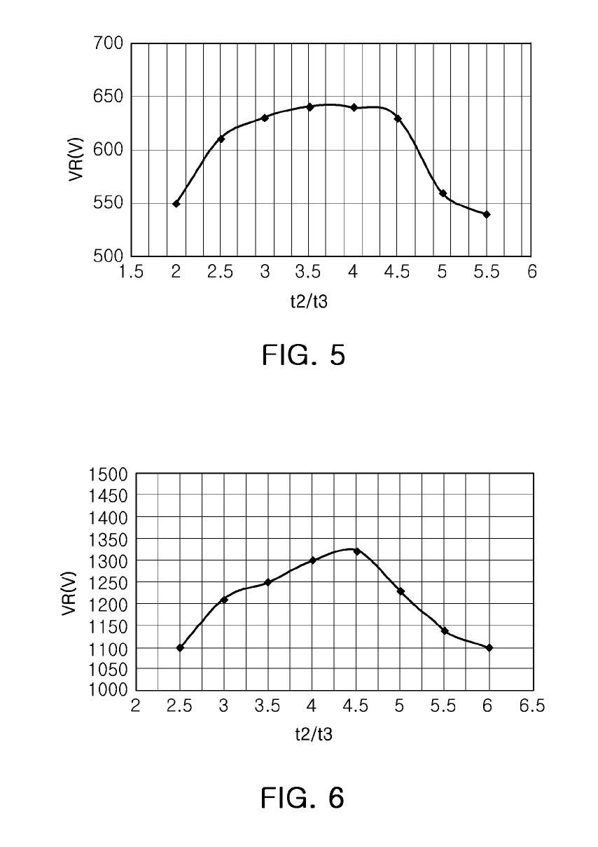

FIG. 5 is a graph showing a VR value according to a t2/t3 value of the power semiconductor device 200 capable of withstanding a reverse voltage of 600V.

The VR value refers to a maximum withstand voltage that the power semiconductor device may withstand.

Referring to FIG. 5, in the case in which the t2/t3 value is less than 2.5, the VR value is decreased to below 600V.

In the case in which the t2/t3 value is less than 2.5, the thickness t3 of the third semiconductor layer 30 is extremely large, thereby decreasing the withstand voltage.

In addition, in the case in which the t2/t3 value exceeds 4.5, the VR value is decreased to below 600V.

In the case in which the t2/t3 value exceeds 4.5, the thickness t3 of the third semiconductor layer 30 becomes extremely small, such that a reach through phenomenon in which the depletion layer contacts the anode metal layer 80 to thereby cause an excessive flow of current may be generated, thereby decreasing the VR value to below 600V.

Therefore, in the case in which the t2/t3 value is 2.5 to 4.5, the VR value may be secured to be 600V or greater, such that the power semiconductor device may withstand the reverse voltage of 600V.

Specifically, in order to allow the power semiconductor device to withstand the reverse voltage of 600V, t3 may be 0.75 μm to 1.86 μm.

FIG. 6 is a graph showing a VR value according to a t2/t3 value of the power semiconductor device 200 capable of withstanding a reverse voltage of 1200V.

The VR value refers to a maximum withstand voltage that the power semiconductor device may withstand.

Referring to FIG. 6, in the case in which the t2/t3 value is less than 3, the VR value is decreased to below 1200 V.

In the case in which the t2/t3 value is less than 3, the thickness t3 of the third semiconductor layer 30 is extremely large, thereby decreasing the withstand voltage.

In addition, in the case in which the t2/t3 value exceeds 5, the VR value is decreased to below 1200V.

In the case in which the t2/t3 value exceeds 5, the thickness t3 of the third semiconductor layer 30 is extremely small, such that a reach through phenomenon in which the depletion layer contacts the anode metal layer 80 to thereby cause an excessive flow of current may be generated, thereby decreasing the VR value to below 1200V.

Therefore, in the case in which the t2/t3 value is 3 to 5, the VR value may be secured on a level of 1200V or greater, thereby withstanding the reverse voltage of 1200V.

Specifically, in order to allow the power semiconductor device to withstand the reverse voltage of 1200V, t3 may be 0.61 μm to 1.67 μm.

The power semiconductor device 200 according to another exemplary embodiment of the present disclosure may further include a fourth semiconductor region of the first conductive type formed on a lower portion of the first semiconductor layer 10 and having an impurity concentration higher than that of the first semiconductor layer 10.

Specifically, the fourth semiconductor region may be formed by injecting a high concentration n-type impurity.

Since the fourth semiconductor region has the high concentration n-type impurity, the power semiconductor device 200 may withstand a higher withstand voltage, than in the case in which the power semiconductor device 200 has only the first semiconductor layer 10.

Therefore, due to the formation of the fourth semiconductor region, the thickness of the power semiconductor device 200 may be reduced.

As set forth above, according to an exemplary embodiment of the present disclosure, since the power semiconductor device has t1/t2 of 15 to 18, it may have a withstand voltage of 600V or greater, a low forward voltage drop (VF), and excellent reverse recovery characteristics.

In addition, according to another exemplary embodiment of the present disclosure, since the power semiconductor device has t1/t2 of 25 to 33, it may have a withstand voltage of 1200V or greater, the low forward voltage drop (VF), and the excellent reverse recovery characteristics.

While exemplary embodiments have been shown and described above, it will be apparent to those skilled in the art that modifications and variations could be made without departing from the spirit and scope of the present disclosure as defined by the appended claims.

What is claimed is:

1. A power semiconductor device, comprising:
a first semiconductor layer of a first conductive type, having a thickness of t1 so as to withstand a reverse voltage of 600V; and
a second semiconductor layer of a second conductive type, formed inside an upper portion of the first semiconductor layer and having a thickness of t2,
wherein t1/t2 is 15 to 18.

2. The power semiconductor device of claim 1, wherein the t1 is 60 μm to 70 μm.

3. The power semiconductor device of claim 1, wherein the t2 is 3.34 μm to 4.67 μm.

4. The power semiconductor device of claim 1, further comprising a third semiconductor layer of the second conductive type, formed inside an upper portion of the second semiconductor layer and having an impurity concentration higher than that of the second semiconductor layer.

5. The power semiconductor device of claim 4, wherein when a thickness of the third semiconductor layer is defined as t3, t2/t3 is 2.5 to 4.5.

6. The power semiconductor device of claim 4, wherein the t3 is 0.75 μm to 1.86 μm.

7. The power semiconductor device of claim 1, further comprising a fourth semiconductor region of the first conductive type, formed on a lower portion of the first semiconductor layer and having an impurity concentration higher than that of the first semiconductor layer.

8. The power semiconductor device of claim 1, further comprising:
an anode metal layer formed on an upper portion of the second semiconductor layer; and
a cathode metal layer formed on a lower portion of the first semiconductor layer.

9. A power semiconductor device, comprising:
a first semiconductor layer of a first conductive type, having a thickness of t1 so as to withstand a reverse voltage of 1200V; and
a second semiconductor layer of a second conductive type, formed inside an upper portion of the first semiconductor layer and having a thickness of t2,
wherein t1/t2 is 25 to 33.

10. The power semiconductor device of claim 9, wherein the t1 is 100 μm to 130 μm.

11. The power semiconductor device of claim 9, wherein the t2 is 3.04 μm to 5.03 μm.

12. The power semiconductor device of claim 9, further comprising a third semiconductor layer of the second conductive type, formed inside an upper portion of the second semiconductor layer and having an impurity concentration higher than that of the second semiconductor layer.

13. The power semiconductor device of claim 12, wherein when a thickness of the third semiconductor layer is defined as t3, t2/t3 is 3 to 5.

14. The power semiconductor device of claim 12, wherein the t3 is 0.61 μm to 1.67 μm.

15. The power semiconductor device of claim 9, further comprising a fourth semiconductor region of the first conductive type, formed on a lower portion of the first semiconductor layer and having an impurity concentration higher than that of the first semiconductor layer.

16. The power semiconductor device of claim 9, further comprising:
an anode metal layer formed on an upper portion of the second semiconductor layer; and
a cathode metal layer formed on a lower portion of the first semiconductor layer.
